(19) United States
(12) Patent Application Publication
(10) Pub. No.: US 2012/0161591 A1
(43) Pub. Date: Jun. 28, 2012

(54) GOLDEN COLOR ENCLOSURE AND METHOD FOR MAKING SAME

(75) Inventors: CHUNG-PEI WANG, Tu-Cheng (TW); MING-YANG LIAO, Tu-Cheng (TW)

(73) Assignee: HON HAI PRECISION INDUSTRY CO., LTD., Tu-Cheng (TW)

(21) Appl. No.: 13/217,247

(22) Filed: Aug. 25, 2011

(30) Foreign Application Priority Data
Dec. 22, 2010 (TW) 099145388

(51) Int. Cl. H04M 1/02; C23C 14/34

(52) U.S. Cl. 312/204; 204/192.15

(57) ABSTRACT

A golden enclosure for a mobile phone includes a shell, a color layer, and a bonding layer. The color layer is formed over an outer surface of the shell. The color layer is comprised of titanium, chromium, and oxygen. The color layer has coordinates (L, a, b) in the CIE Lab color space. The “L” coordinate is in a range from bout 46.72 to bout 61.45. The coordinate is in a range from about 4.91 to about 16.1. The “b” coordinate is in a range from about 39.49 to about 55.18. The bonding layer is sandwiched between the shell and the color layer.

### BACKGROUND

1. Technical Field

The disclosure generally relates to enclosures for mobile phones, and particularly to an enclosure with golden color, and a method for making the enclosure.

2. Description of Related Art

It is well known that many users are interested in portable electronic devices with various colors, such as a mobile phone with golden color. Generally, such mobile phones are made by forming a gold film on the enclosure thereof. In existing technology, a golden enclosure is made by applying a gold coating on a surface of the enclosure, using gold plating. However, the golden enclosure is expensive as well the gold plating process is complicated and not cost-efficient. In addition, the golden enclosure is generally required to be hard to have long wear resistance property, which may probably result in a difference of the thermal expansion between the golden coating and the enclosure. In such a case, the golden coating is difficult to firmly attached on the surface of the enclosure, and it is easy to peel off the enclosure during normal wear and tear.

Therefore, what is needed, is a golden enclosure and a method for making the golden enclosure, which can overcome the above shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the golden enclosure and the method for making the golden enclosure. Moreover, in the drawings, like reference numerals designate corresponding parts throughout the several views.

FIG. 1 is an isometric view of a mobile phone with a golden enclosure, in accordance with an embodiment.

FIG. 2 is a cross sectional view of the golden enclosure of FIG. 1, taken from line II-II.

FIG. 3 is a flowchart of a method for making the golden enclosure of FIG. 2.

### DETAILED DESCRIPTION

Embodiment of the golden enclosure and the method for making the golden enclosure will now be described in detail below and with reference to the drawings.

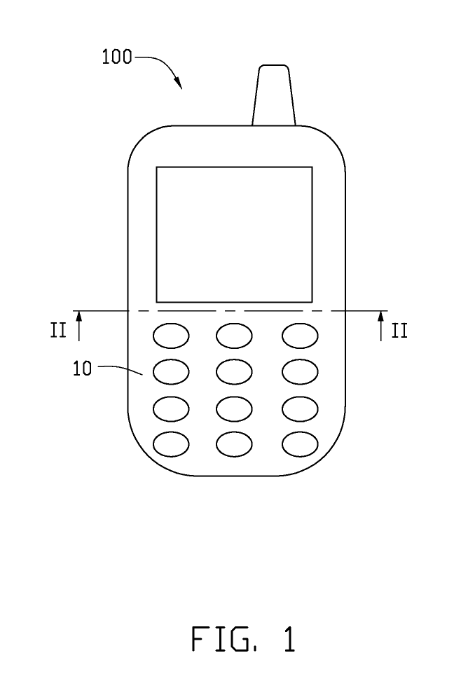

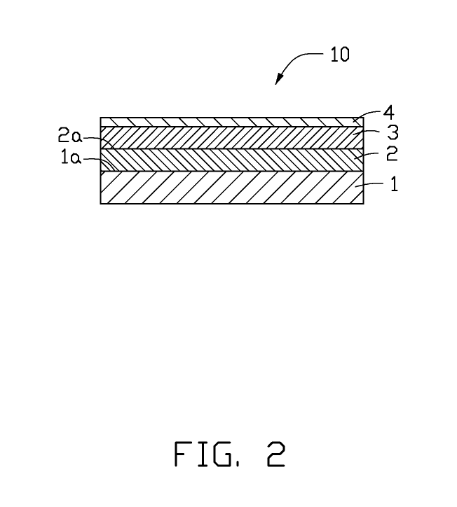

A golden enclosure for use in a portable electronic device is disclosed. Referring to FIG. 1 and FIG. 2, a golden enclosure 10, in accordance with the disclosure, is shown, here, installed on a mobile phone 100. The golden enclosure 10 includes a shell 1, a bonding layer 2, a color layer 3, and a protective layer 4. The bonding layer 2 is formed on the shell 1. The color layer 3 is formed on the bonding layer 2, and the protective layer 4 is further formed on the color layer 3.

The shell 1 is made of metal, plastic or ceramic. In this embodiment, the shell 1 is made of stainless steel. The shell 1 is generally plate-shaped, and has a first surface 1a. At least a portion (such as a central portion) of the first surface 1a is rough using a sandblasting process, thereby facilitating a bond of bonding layer 2 to the first surface 1a of the shell 1. That is, the bonding layer 2 can be firmly bonded to the shell 1. The bonding layer 2 is comprised of chromium nitride (CrN) or titanium nitride (TiN). In this embodiment, the color layer 3 has a second surface 2a opposite to the first surface 1a of the shell 1. The color layer 3 formed on the second surface 2a of the bonding layer 2, and is comprised of titanium (Ti) and chromium (Cr), as well as oxygen. The color layer 3 originally appears golden. The protective layer 4 is made of light-pervious material, such that the enclosure 10 has golden color, as seen from a side of the protective layer 4 facing away from the color layer 3. In this embodiment, the protective layer 4 can be used to protect the color layer 3 from damage. In a typical example, the protective layer 4 is an anti-fingerprint (AFP) paint coating. Overall, in this embodiment, a Vickers hardness of the golden enclosure 10 is equal to or more than 500 HV.

For illustrating purposes and operation of the golden enclosure 10, the color layer 3 has coordinates (L, a, b) in the Commission International de l'Eclairage (CIE) Lab color space. In this embodiment, the “L” coordinate is in a range from bout 46.72 to about 61.45. The “a” coordinate is in a range from bout 4.91 to about 16.1, and the “b” coordinate is in a range from bout 39.49 to about 55.18. Typical coordinates (L, a, b) of the color layer 3, can be for example (60.01, 6.6, 45.07), (46.72, 14.42, 39.49), (48.63, 11.32, 51.21), (61.45, 4.91, 41.75), (46.97, 16.10, 47.21), (51.61, 12.35, 55.18), or (59.89, 6.22, 45.18). With this configuration, a golden enclosure 10 with superior gold color is ensured.

In this embodiment, the golden enclosure 10 has maximum wear resistance property as the bonding layer 2 is firmly bonded to the shell 1, and the hardness of the golden enclosure 10 is relatively high.

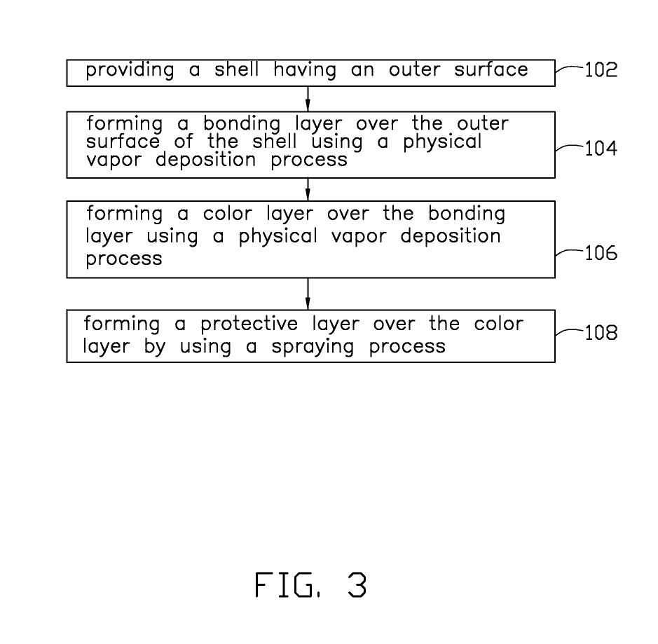

Referring to FIG. 2 and FIG. 3, a method for making the golden enclosure 10 is summarized below.

In step 102, the first surface 1a of the shell 1 is rough machined using a lathe.

In step 104, the bonding layer 2 is formed on the first surface 1a of the shell 1 by applying physical vapor deposition, using CrN or TiN. In this embodiment, the bonding layer 2 is formed on the shell 1 by applying magnetic sputtering, using CrN. In one typical example, a chamber receiving the shell 1 is used to firstly provide a vacuum environment for the shell 1. Then reactive gas such as nitrogen, together with an inert gas, such as argon, krypton or helium is introduced into the chamber. A target material is sputtered onto the first surface 1a of the shell 1. In this embodiment, the target material is chromium. The target material is heated up to reach a high temperature. When the gas atoms, such as the inert gas atoms are ionized. The gas ions collide with atoms of the target material. The atoms of the target material get energy and momentum from the gas ions, thus ejecting from the target material, and then reaching the first surface 1a of the shell 1 to be deposited thereon, forming the bonding layer 2. Generally, during magnetic sputtering process, a magnet is provided for facilitating ionization of gases around the target material, increasing the probability of collision between gas ions and the target material and hence improving the speed of sputtering. In this embodiment, as the first surface 1a is rough machined prior to forming the bonding layer 2 thereon, the bonding layer 2 can be firmly bonded to the shell 1.

In step 106, the color layer 3 is formed on the bonding layer 2 also by applying magnetic sputtering for about 20 minutes to about 30 minutes. In this embodiment, titanium and chromium are used simultaneously as target materials. Reactive gas such as oxygen and inert gas, such as argon is introduced into the chamber. The oxygen in configured for reacting with the titanium and the chromium to form the color layer 3. In operation, a flow rate of the oxygen can be adjusted to form a color layer 3 with varied hardness. In this embodiment, a flow rate of the oxygen is in a range from about 285 standard cubic centimeter per minute (sccm) to about 315 sccm, for example 300 sccm. A flow rate of the argon is in a range from about 190 sccm to about 210 sccm, for example 200 sccm.

In step 106, the target material is heated to reach a high temperature. When the argon atoms are ionized. The argon ions collide with atoms of the target materials simultaneously. The atoms of the target materials get energy and momentum from the argon ions, thus ejecting from the target materials to react with the oxygen, and then reaching the second surface 2a of the bonding layer 2 to be deposited thereon, forming the color layer 3. In this embodiment, a working voltage of about 195 volts to about 205 volts is applied during the magnetic sputtering process. The atoms of the titanium target material get energy and momentum from the argon ions with a sputter power of about 22 KW to about 28 KW, for example, 25 KW. The atoms of the chromium target material get energy and momentum from the argon ions with a sputter power at about 5 KW˜7 KW, for example, 6 KW. In this embodiment, the shell 1 can be rotated to ensure the color layer 3 is uniformly deposited on the bonding layer 2. The shell 1 can be rotated at a speed of about 8 rpm to about 10 revolution per minute (rpm).

In step 108, the protective layer 4 is further formed on the bonding layer 2 by applying for example, a spray.

When the protective layer 4 is formed on the color layer 3, the golden enclosure 10 is obtained.

It is understood that the above-described embodiment are intended to illustrate rather than limit the disclosure. Variations may be made to the embodiment without departing from the spirit of the disclosure. Accordingly, it is appropriate that the appended claims be construed broadly and in a manner consistent with the scope of the disclosure.

What is claimed is:

1. A golden enclosure for a mobile phone, comprising:
a shell;
a color layer formed over an outer surface of the shell, the color layer comprised of titanium, chromium, and oxygen, the color layer having coordinates (L, a, b) in the CIE Lab color space, the “L” coordinate being in a range from about 46.72 to about 61.45, the “a” coordinate being in a range from about 4.91 to about 16.1, and the “b” coordinate being in a range from bout 39.49 to about 55.18; and
a bonding layer sandwiched between the shell and the color layer.

2. The golden enclosure of claim 1, wherein the bonding layer is comprised of chromium nitride or titanium nitride.

3. The golden enclosure of claim 1, wherein a Vickers hardness of the golden enclosure is equal to or more than 500 HV.

4. The golden enclosure of claim 1, further comprising a protective layer formed on the color layer, the protective layer being light-pervious and configured for protecting the color layer.

5. The golden enclosure of claim 1, wherein a protective layer is an anti-fingerprint coating.

6. The golden enclosure of claim 1, wherein the shell is made of material selected from a group consisting of metal, plastic and ceramic.

7. The golden enclosure of claim 6, wherein the shell is made of stainless steel.

8. A method for making a golden enclosure for a mobile, comprising:
providing a shell having an outer surface;
forming a bonding layer over the outer surface of the shell using a physical vapor deposition process; and
forming a color layer over the bonding layer using a physical vapor deposition process, the color layer comprised of chromium, titanium and oxygen, the color layer having coordinates (L, a, b) in the CIE Lab color space, the “L” coordinate being in a range from about 46.72 to about 61.45, the “a” coordinate being in a range from about 4.91 to about 16.1, and the “b” coordinate being in a range from about 39.49 to about 55.18.

9. The method of claim 8, wherein the bonding layer is formed on the shell using a magnetic sputtering process, wherein target material is chromium and reactive gas is nitrogen.

10. The method of claim 8, wherein the color layer is formed on the bonding layer using a magnetic sputtering process, wherein target material includes a titanium target and a chromium target, and reactive gas is oxygen.

11. The method of claim 10, wherein the titanium target is sputtered at a sputter power of about 22 KW˜28 KW in an argon atmosphere, and the chromium target is sputtered at a sputter power of about 5 KW to 7 KW in the argon atmosphere.

12. The method of claim 10, wherein the magnetic sputtering process for both the titanium target and the chromium target is performed for about 20 minutes to about 30 minutes, with a working voltage of about 195 volts to about 205 volts.

13. The method of claim 10, wherein the shell is rotated at a rotation speed of about 8 rotations per minute to 10 rotations per minute when the magnetic sputtering process is performed.

14. The method of claim 10, wherein a flow rate of the oxygen is in a range from about 285 standard cubic centimeters per minute to about 315 standard cubic centimeters per minute.

15. The method of claim 8, wherein the outer surface of the shell is roughened prior to forming the bonding layer using a sandblasting process.
